(19) United States
(12) Patent Application Publication
(10) Pub. No.: US 2003/0008629 A1
(43) Pub. Date: Jan. 9, 2003

(54) Circuit configuration with bandpass filters

(76) Inventors: Martin Tegeler, Aying (DE); Georg Lipperer, Munchen (DE)

Correspondence Address: LERNER AND GREENBERG, P.A., Post Office Box 2480, Hollywood, FL, 33022-2480, US

(21) Appl. No.: 10/208,414

(22) Filed: Jul. 29, 2002

Related U.S. Application Data
(63) Continuation of application No. PCT/DE01/00214, filed on Jan. 18, 2001.

(30) Foreign Application Priority Data
Jan. 28, 2000 (DE) 100 03 704.6

(51) Int. Cl. H03K 5/00; H03B 1/00; H03H 9/00; H04B 1/10

(52) U.S. Cl. 455/307; 327/552; 333/186

(57) ABSTRACT

A circuit configuration for the bandpass filtering of a high-frequency signal with a large bandwidth, includes a plurality of bandpass filters which have staggered passbands and are disposed in parallel. A changeover switch which is integrated in a semiconductor module is connected to the bandpass filters on the line side. The number of outputs of the semiconductor module is equal to the number of bandpass filters. This improves the circuit configuration with respect to isolation, space requirement, component requirement and costs. Such circuit configurations can be utilized in the field of mobile radio communications.

### CROSS-REFERENCE TO RELATED APPLICATION

This application is a continuation of copending International Application No. PCT/DE01/00214, filed Jan. 18, 2001, which designated the United States and was not published in English.

### BACKGROUND OF THE INVENTION

Field of the Invention

The invention relates to a circuit configuration with at least two bandpass filters.

In some applications in high-frequency technology, for instance mobile radio technology, the bandwidth of a signal that is to be filtered can be larger than the bandwidth of existing bandpass filters of sufficient quality. The quality of a bandpass filter is typically defined as the quotient of resonance frequency and bandwidth. A known configuration for solving that problem is to place two bandpass filters with staggered passbands parallel to each other in a signal path. The two signal paths are reunified on the output side, i.e. after the filtering. It is also problematic that the parallel filters have an adverse effect on one another with respect to their filter characteristics. For instance, interference signals or noise can be passed by one bandpass filter, whereas the actual wanted signal resides in the passband of a filter that passes parallel to the noise signal. For that reason, the signal paths adjoining the inputs of the bandpass filters must not be simultaneously active. An optimally large isolation of the active signal path relative to the inactive signal path is desirable.

The disconnection of the unneeded signal paths can be realized in a known manner with a PIN (Positive Intrinsic Negative) diode switch, in which PIN diodes are disposed in series with appertaining parallel bandpass filters. The disadvantages of that configuration are its large space requirement and the number of components of such a circuit which is built from discrete elements. Those disadvantages are particularly serious when such circuits are utilized in the field of mobile radio communications. Reducing the dimensions and weight of terminal devices and the associated costs are significant development goals in the field of mobile radio communications.

### SUMMARY OF THE INVENTION

It is accordingly an object of the invention to provide a circuit configuration for filtering a high-frequency signal with a plurality of parallel bandpass filters, which overcomes the hereinafore-mentioned disadvantages of the heretofore-known devices of this general type and which has a large isolation and a small demand for space and components.

With the foregoing and other objects in view there is provided, in accordance with the invention, a circuit configuration, comprising a given number (at least two) of bandpass filters. Each of the bandpass filters has an input and an output and the outputs are connected to each other. An integrated semiconductor module has a circuit part with a number of signal paths corresponding to the given number. The signal paths have input sides connected to each other and output sides each leading out of the integrated semiconductor module and connected to the input of a respective one of the bandpass filters. A drive circuit is connected to the signal paths for switching a signal to be supplied on one of the input sides to the input of one of the bandpass filters. Output stages are each disposed in a respective one of the signal paths. The output stages have supply current feeds to be switched on or off by the drive circuit.

In other words, a high-frequency signal which is routable to the bandpass filters is already split into a plurality of signal paths in an integrated semiconductor module disposed upstream of the bandpass filters. In addition, the integrated semiconductor module includes a drive circuit for switching the individual signal paths, which is connected to the partitioned signal paths. The semiconductor module that is connected to the bandpass filters on the line side thus has as many signal outputs as there are parallel bandpass filters. Each signal output, i.e. signal path, of the semiconductor module is connected to an input of a bandpass filter. The drive circuit that is disposed in the semiconductor module ensures that only one signal path is switched through onto a respective bandpass. This prevents parallel bandpass filters from being active at the same time and thereby suppresses interference signals and noise. The outputs of the bandpasses are connected to one another. A filtered high-frequency signal can be tapped at this common output.

The integration of the circuit for separating the signal paths of a high-frequency signal, and the driving or changeover of the individual signal paths that are connected to the inputs of bandpass filters, obviates a circuit for signal separation and changeover composed of discrete elements such as PIN diodes. This permits a reduction of the space requirement and of the number of required components. Furthermore, the above-described circuit configuration makes it possible to provide a greater isolation with respect to the inactive signal paths.

The output stage which is to be supplied with a supply voltage is disposed in each of the signal paths in the semiconductor module. The drive circuit influences the signal paths in such a way that the current supply of the output stages of the unneeded signal paths can be interrupted.

In accordance with another feature of the invention, the output stages that are disposed in the semiconductor module, and can be switched on and off by the drive circuit, are simultaneously converter circuits which convert a difference signal to be supplied on the input side into a signal that can be carried on a single line.

In accordance with a further feature of the invention, the output stages which convert a difference signal into a signal that can be carried on a single line (a single ended signal), each include a difference amplifier and a downstream emitter follower.

In accordance with an added feature of the invention, surface wave filters (SAW) are employed as bandpass filters. These filters can be housed in a common housing.

In accordance with a concomitant feature of the invention, the parallel bandpass filters have staggered passbands.

Other features which are considered as characteristic for the invention are set forth in the appended claims.

Although the invention is illustrated and described herein as embodied in a circuit configuration with bandpass filters, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a schematic and block circuit diagram of a principal circuit configuration according to an exemplary embodiment of the present invention; and

FIG. 2 is a schematic and block circuit diagram of a principal circuit configuration with PIN diode switches, according to the prior art.

### DESCRIPTION OF THE PREFERRED EMBODIMENTS

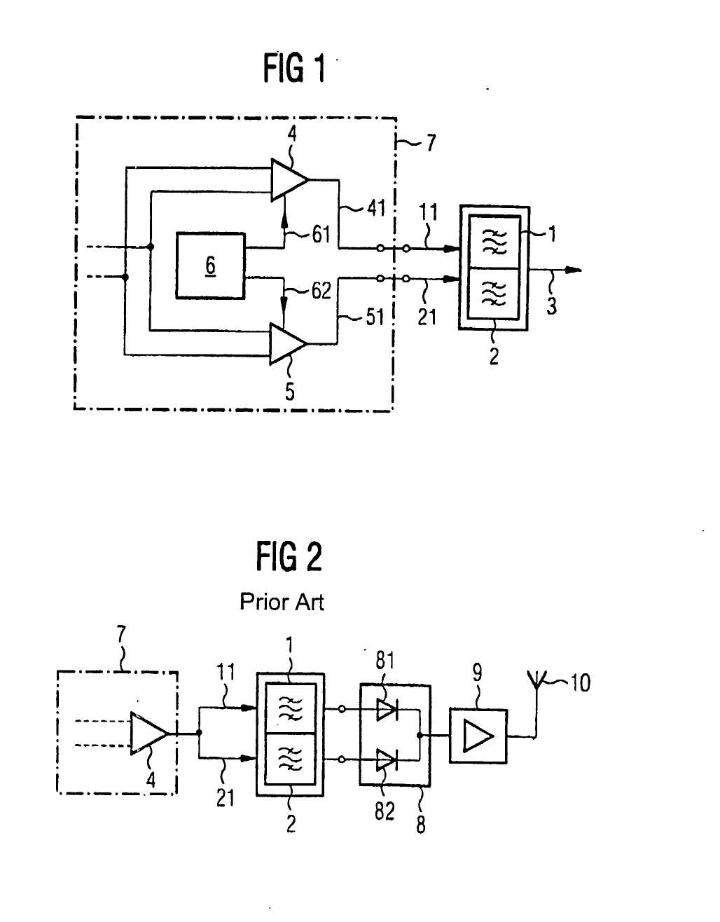

Referring now to the figures of the drawings in detail and first, particularly, to FIG. 1 thereof, there is seen a circuit configuration according to the invention with two bandpass filters which are connected parallel to one another. The circuit is suitable for frequencies of approximately 1 gigahertz.

As can be seen from FIG. 1, two bandpass filters 1, 2 are connected in parallel and disposed in a common housing. The bandpass filters each include an input 11, 21 and outputs which are connected to a common output 3. A high-frequency signal can be fed to the inputs 11, 21 of the bandpass filters. A semiconductor module 7 which is connected to the bandpass filters on the line side has a circuit part with signal paths 41, 51. The high-frequency signal is split into the different signal paths 41, 51 in the semiconductor module 7. The number of signal paths, i.e. the number of paths leading out of the semiconductor module 7 on the output side, corresponds to the number of bandpass filters 1, 2, that is to say the number of bandpass filter inputs 11, 21. Output stages 4, 5, which are disposed in the signal paths 41, 51, convert a high-frequency signal (in this case a difference signal) that is to be supplied to the present circuit into an output signal that can be carried on one line. In a difference signal, the actual information content is found in the difference between two signals. In contrast, the output signal is carried on a single line which is referred to a reference potential (ground). The output stages 4, 5 each include a respective difference amplifier with a downstream emitter follower for this purpose. Due to the above-described requirement that only one signal path be active at a given time, a drive circuit 6 is provided, which is connected to the output stages 4, 5. The output stages 4, 5 have supply current feeds 61, 62 to be switched on and off by the drive circuit 6. Therefore, the drive circuit 6 disconnects the supply current of the respective unneeded output stage.

FIG. 2 represents a prior art configuration for realizing a drive circuit formed of parallel bandpass filters with PIN diodes, such as is utilized in mobile radio telephones. In the illustrated example, the integrated semiconductor module 7 is a modulator module in which digital signals are modulated onto an analog signal in a non-illustrated manner. The resulting signal is fed to a difference amplifier 4. The semiconductor module 7 has only one output (single-ended). This signal is first split outside the semiconductor module 7 into two signal paths which are connected to the two inputs 11, 21 of the two bandpass filters (SAW filters) 1, 2. Respective PIN diodes 81, 82 are connected to the two outputs of the bandpass filters 1, 2. These two PIN diodes 81, 82 are part of a PIN diode switch 8, which includes additional non-illustrated elements for driving the PIN diodes. Outputs of the PIN diodes 81, 82 are connected and linked through a power amplifier 9 to a mobile radio antenna 10. An antenna changeover switch that is typically disposed upstream of the antenna is not shown. The configuration requires a large amount of space, because the PIN diode changeover switch 8 is composed of discrete elements. Furthermore, it lends the overall circuit configuration a relatively high weight and thus gives rise to high costs.

On the other hand, when, in accordance with FIG. 1, the high-frequency signal is already split in a semiconductor module 7 which is connected to the bandpass filters on the line side, it is possible to achieve a large isolation (approximately 66 dB) of the active signal path from the inactive signal path. Furthermore, substantial savings in space, weight and components are gained as compared to a structure with PIN diodes.

The present exemplary embodiment of the invention is applied in mobile radio technology, for example. The bandwidth of the high-frequency signal that can be supplied on the input side is 70 megahertz in this case. The signal frequencies are between 890 and 960 megahertz. This bandwidth is too large for only one bandpass filter (surface wave filters are utilized in this case). For this reason, two bandpass filters with staggered passbands must be connected in parallel. The output 3 of the circuit configuration can be connected to an antenna of a mobile radio telephone through an amplifier stage. The semiconductor module 7, which is connected to the bandpass filters on the line side as described, can be a modulator module which modulates digital signals, for instance voice signals, onto an analog carrier frequency. This modulated signal is then split in the described manner and fed to the output stages 4,5.

In modifications of the embodiment described in connection with FIG. 1, more than two bandpass filters can be connected in parallel for the purpose of expanding the bandwidth of the circuit.

We claim:

1. A circuit configuration, comprising:
a given number of bandpass filters, said given number equal to at least two, each of said bandpass filters having an input and an output, and said outputs connected to each other;
an integrated semiconductor module;
a circuit part disposed in said integrated semiconductor module, said circuit part having a number of signal paths corresponding to said given number, said signal paths having input sides connected to each other and output sides each leading out of said integrated semiconductor module and connected to said input of a respective one of said bandpass filters;
a drive circuit connected to said signal paths for switching a signal to be supplied on one of said input sides to said input of one of said bandpass filters; and
output stages each disposed in a respective one of said signal paths, said output stages having supply current feeds to be switched on and off by said drive circuit.

2. The circuit configuration according to claim 1, wherein said output stages convert a difference signal to be supplied on said input side into a signal to be carried on one line.

3. The circuit configuration according to claim 2, wherein each of said output stages has a difference amplifier and a downstream emitter follower.

4. The circuit configuration according to claim 1, wherein said bandpass filters are surface wave filters housed in a common housing.

5. The circuit configuration according to claim 1, wherein said bandpass filters have staggered passbands.
